(19) United States
(12) Patent Application Publication
(10) Pub. No.: US 2008/0090022 A1
(43) Pub. Date: Apr. 17, 2008

(54) High rate, continuous deposition of high quality amorphous, nanocrystalline, microcrystalline or polycrystalline materials

(75) Inventor: Stanford R. Ovshinsky, Bloomfield Hills, MI (US)

Correspondence Address: David W. Schumaker;ENERGY CONVERSIOIN DEVICES, INC., 2956 Waterview Drive, Rochester Hills, MI, 48309, US

(73) Assignee: Energy Conversion Devices, Inc.

(21) Appl. No.: 11/546,619

(22) Filed: Oct. 12, 2006

(51) Int. Cl. C23C 16/00; H05H 1/24

(52) U.S. Cl. 427/569; 427/248.1; 118/723 R

(57) ABSTRACT

An apparatus and a method for high rate deposition of thin film materials. The method including the steps of (1) generating a supply of activated species from an energy transferring gas, through the use of a plasma; (2) separating the charged species from the non-charged species of the activated species (optionally through the use of an electrically biased screen or mesh), (3) transporting the non-charged species to a collision region (through the use of the substantial pressure differential and transonic velocity of the energy transferring gas); (4) introducing a precursor deposition feedstock gas into the collision region and; (5) producing large quantities of desirable deposition species within said collision region via the collision of non-charged species of said energy transferring gas with molecules within the precursor deposition feedstock gas; and (6) depositing, at a high deposition rate, quality thin film material onto a substrate which is adjacent to the collision. The apparatus will allow for the formation of a filtered, neutralized plasma from which non-single crystal semiconductors having fewer than 5.0×10¹⁴/cm³ subgap defects.

### FIELD OF THE INVENTION

The instant invention relates generally to the high rate deposition of high quality amorphous, nanocrystalline, microcrystalline or polycrystalline materials. More specifically, the present invention the instant invention relates to a method of generating a high density of only desired species for the deposition of thin films of material onto the surface of a substrate. Whereas, it has previously been possible to either deposit relatively poor quality material amorphous semiconductor alloy material at a relatively high rate of deposition, or to deposit relatively high quality material at a relatively low rate of deposition; the concepts disclosed by the instant invention now make it possible to obtain the best of both worlds and deposit high quality thin film material at very high rates of deposition. The result is the ability to fabricate high quality films in a commercially significant, economical manner and, in turn, allows for the deposition of photovoltaic semiconductor materials and solar cells having significantly enhanced photovoltaic conversion efficiencies.

The method herein creates a deposition region which is composed primarily of desired species for deposition of the high quality photovoltaic semiconductor materials. The method activates an energy transferring gas using an external source of energy for generating activated species (ionic, free radical or otherwise excited neutrals). Once the activated species are created, charged species are removed from the activated energy transferring gas, and the energy from the remaining non-charged species of the energy transferring gas is transferred to a remotely located deposition gas through, collisions therewith.

### BACKGROUND OF THE INVENTION

Crystalline materials which feature a regular lattice structure were formerly considered essential in the manufacture of reliable semiconductor devices. While solar cells, switches and the like having favorable characteristics continue to be so manufactured, it is recognized that preparation of crystalline materials introduces substantial costs into the semiconductor industry. Single crystal silicon and the like must be produced by expensive, energy intensive, high-temperature, time-consuming methods. Czochralski and like crystal growth techniques involve the growth of an ingot which must then be sliced into wafers and are thus inherently batch processing concepts.

Stanford R. Ovshinsky (the instant inventor) pioneered developments in the field of devices formed of amorphous and disordered semiconductors and other materials which offer a significant reduction in production costs. In particular, solar cell technology, which is dependent upon the production of a large number of devices to comprise a panel, is critically affected by processing economies. The feasibility of semiconductor devices produced by amorphous, as opposed to crystalline, materials is disclosed, for example, in U.S. Pat. No. 4,217,374 of Ovshinsky and Izu. A silicon solar cell produced by successive RF plasma glow discharge deposition of layers of various conductivities and dopings and its process of manufacture are described in U.S. Pat. No. 4,226,898 of Ovshinsky.

As will be discussed more fully herein below, The plasma which creates the devices discussed herein is described as being a “zoo” populated by numerous and rapidly changing exotic activated species of the precursor gaseous mixture introduced thereinto; the species formed by the fragmentation, ionization, radicalization and recombination of that gaseous mixture. It is known that the composition and characteristics of the deposited semiconductor alloy material will depend, inter alia, upon the particular excited species producing that deposit. The present invention gives us a method of controlling the species of this “zoo” to benefit the deposition of desired materials and thin films thereof.

Because of the “zoo” like nature of the deposition plasma, many researchers in the field of amorphous silicon alloy materials have espoused the theory that an inherent limitation exists as to the rate at which high quality amorphous silicon alloy material can be grown. That is, it is well known that the photo-induced Staebler-Wronski degradation of amorphous silicon is much more severe when the material is produced at high deposition rates.

As used herein, high quality amorphous silicon material will be defined as material which exhibits a low density of electronic defect states in the band gap thereof so as to provide for good electrical characteristics (such as high photoconductivity, low dark conductivity ability to be doped by the addition of impurity atoms).

FIG. 1 is a depiction of the species in the “zoo” of a silane plasma. These species include a variety of ions, radicals, and energized neutrals. Specifically the plasma contains ions, radicals and neutrals of such as SiH3, SiH2, SiH, SI, and H. Further it is known that the photo-induced Staebler-Wronski degradation of amorphous silicon is closely related to the density of incorporated SiH₂ in the amorphous silicon material. Finally, it is also known that the most desirable species for deposition of high quality photovoltaic materials is SiH₃. Of the types of species (ions, radicals or neutrals), deposition of neutral radicals is believed to make the highest quality materials. This relates also to the sticking coefficient of the different types of species (even free radicals can be bad if they are not neutral). Ions have high energy and will impart that energy to the surface of the growing material, and this may cause deleterious effects on the depositing amorphous materials. Also, ions readily react with the growing thin film and will practically stick where they land. Further high energy ions can bombard the surface and remove deposited materials. Radicals have a low enough sticking coefficient to bond only in energetically desirable sites on the growing surface.

Amorphous thin film semiconductor alloys have gained acceptance for the fabrication of electronic devices such as photovoltaic cells, photoresponsive and photoconductive devices, transistors, diodes, integrated circuits, memory arrays and the like. This is because the amorphous thin film semiconductor alloys (1) can now be manufactured by relatively low cost continuous processes, (2) possess a wide range of controllable electrical, optical, chemical, mechanical and structural properties and (3) can be deposited to cover relatively large areas. Among the semiconductor alloy materials exhibiting the greatest present commercial significance are amorphous silicon, germanium and silicon-germanium based alloys (also containing, for example, hydrogen or fluorine). Such alloys have been the subject of a continuing development effort on the part of the assignee of the instant invention, said alloys being investigated and utilized as possible candidates from which to fabricate a wide range of semiconductor, electronic and photoresponsive devices.

The assignee of the present invention is recognized as the world leader in photovoltaic technology. Photovoltaic devices produced by said assignee have set world records for photoconversion efficiency and long term stablility under operating conditions (the efficiency and stability considerations will be discussed in great detail hereinbelow). Additionally, said assignee has developed commercial processes for the continuous roll-to-roll manufacture of large area photovoltaic devices. Such continuous processing systems are disclosed in the following U.S. Patents, disclosures of which are incorporated herein by reference: U.S. Pat. No. 4,400,409, for A Method Of Making P-Doped Silicon Films And Devices Made Therefrom; U.S. Pat. No. 4,410,588, for Continuous Amorphous Solar Cell Production Systems; and U.S. Pat. No. 4,438,723, for Multiple Chamber Deposition and Isolation System And Method. As disclosed in these patents a web of substrate material may be continuously advanced through a succession of operatively interconnected, environmentally protected deposition chambers, wherein each chamber is dedicated to the deposition of a specific layer of semiconductor alloy material onto the web or onto a previously deposited layer. In making a photovoltaic device, for instance, of n-i-p type configurations, the first chamber is dedicated for the deposition of a layer of an n-type semiconductor alloy material, the second chamber is dedicated for the deposition of a layer of substantially intrinsic amorphous semiconductor alloy material, and the third chamber is dedicated for the deposition of a layer of a p-type semiconductor alloy material. The layers of semiconductor alloy material thus deposited in the vacuum envelope of the deposition apparatus may be utilized to form photoresponsive devices, such as, but not limited to, photovoltaic devices which include one or more cascaded n-i-p type cells. By making multiple passes through the succession of deposition chambers, or by providing an additional array of deposition chambers, multiple stacked cells of various configurations may be obtained. Note, that as used herein the term “n-i-p type” will refer to any sequence of n and p or n, i and p semiconductor alloy layers operatively disposed and successively deposited to form a photoactive region wherein charge carriers are generated by the absorption of photons from incident radiation.

Plasma enhanced chemical vapor deposition (PECVD) has consistently demonstrated the ability to provide high quality deposited thin films of semiconductor alloy material. The quality of thin films of deposited semiconductor alloy material typically is measured in terms of the density of localized defect states which exist in the energy gap thereof. However, other parameters may materially affect, in a deleterious fashion, the electronic and optical properties of the depositing semiconductor film. Despite the relatively low defect density present in the energy gap of PECVD deposited silicon alloy material, the defect density can still be reduced by the inventions taught herein. This is particularly true in terms of narrow band gap semiconductor alloy materials fabricated from silicon germanium alloys wherein (in the best 1.3-1.65 eV material) the density of localized defect states in the energy gap still remains in the mid-10¹⁶ defects/cm³/eV range. In order to obtain high quality material exhibiting even this relatively high defect density, it is necessary to introduce different, but complementary compensating elements into the plasma. Further, and very importantly, regardless of the power employed, the rate of deposition remains too low to be competitive with fossil fuel. It has been demonstrated that the introduction of a first compensating element, such as hydrogen or fluorine, is effective in reducing the localized states in the energy gap of silicon alloy material. Also, fluorine increases coordination in the deposited thin-film.

Unfortunately, in a commercial fabrication process, a significant problem has been found to exist in the deposition of high quality silicon alloy material. When the rate of deposition of the amorphous silicon semiconductor alloy material (and indeed the deposition rate of any semiconductor or insulating material) is raised in order to deposit that material in a commercially economical manner, the quality of the deposited material deteriorates. One of the causes of such deterioration is gas phase nucleation and the formation of powder in the plasma, which forms when molecules of the depositing material stick to each other instead of depositing on the intended substrate and form particles of material which eventually can cause undesired issues in the deposited materials. More particularly, previous attempts to increase the rate of deposition of semiconductor alloy material (e.g., from as little as 10 Angstroms per second to 12 Angstroms per second), as by increasing the power being utilized, results in a more energetic plasma. This more energetic plasma either changes the plasma reaction kinetics to produce a different set of ions and free radicals, or that energetic plasma fails to allot the compensating elements a sufficient period of time in which to interact with the host matrix of the depositing semiconductor alloy material for relaxing the strained, broken, dangling, stressed or otherwise deviant bonding configurations thereof. Although the foregoing paragraphs have dealt primarily with the deposition of narrow band gap semiconductor alloy material, the same deterioration in material quality (an increase in the density of defect states and increased powder formation) with increasing power is universally reported and has been experimentally seen in the plasma deposition of wide band gap semiconductor alloy material.

Experimental observations of the electronic defect density of multi-element amorphous silicon alloy films deposited from a great number of different gas chemistries (using both r.f. and microwave energy) reveal that deposited thin films deposited from combinations of precursor gases having comparable individual “deposition efficiencies” exhibit the highest quality electronic properties. Based upon those observations, it becomes possible to modify the characteristics of the deposited thin film material. However, the degree of modification possible is limited because of the uncontrollable chemistry provided by the “zoo” of chemical reactions generated in the highly energetic plasma. More particularly, as stated above, within the plasma, the precursor feedstock gases experience multiple collisions with plasma electrons to generate a host of free radicals and ions. It is necessary to pay the most attention to the neutral free radicals which have been generated because experience has demonstrated that free radicals represent the plasma species which is deposited onto a substrate.

With respect to those neutral free radicals, note that there exists a distribution of free radicals depending upon the electron temperature, the electron density and the residence time of the gaseous precursor exposed to the electromagnetic field. The residence time dependence results from multiple electron collisions or collisions between previously excited free radicals and feedstock molecules or between two or more free radicals. In a silane feedstock plasma, the lowest energy member of the possible free radicals which can is neutra be generated is SiH₄*, with higher energy members including SiH₃*, SiH₂*, SiH* and Si*. However, it is possible to tailor the distribution of species and as such excited neutral helium radicals may be used to create a predominance of SiH₃* via a reaction such as:

He*+SiH₄→SiH₃*+He+H

Artisans have appreciated that if it were possible to control plasma chemistry, it would be possible to generate only the desired free radical or ionic species, and it would therefore be possible to deposit only the highest possible quality of thin film material. Further it is understood that if only desired free radical or ionic species are generated within the plasma, the material can be deposited at very high rates because it no longer is necessary to be sure that the dangling, broken, bent, strained, stressed, or other deviant bonding configurations of the host matrix of the depositing material have a chance to be healed through the use of such compensating elements as hydrogen and/or fluorine.

The instant inventors and others have looked for ways to control the plasma to generate only the desired free radical or ionic species. New, fundamental and basic improvements are still a needed in the art, particularly for a process and apparatus which can deposit high quality amorphous, nanocrystalline, microcrystalline or polycrystalline materials at high rates, and importantly on a continuous roll-to-roll basis.

### BRIEF SUMMARY OF THE INVENTION

The instant invention presents a scientific and technological step-function advance that will revolutionize living conditions on Earth and the world economy by enabling, for the first time, a technology that can displace fossil fuels as the primary source of the world's energy. The invention provides a fundamental contribution to plasma chemistry and physics and exploits the advance to achieve a process system that can produce not just megawatts of photovoltaic material, but rather gigawatts in a machine that is the length of a football field that is capable of producing miles and miles of photovoltaic material in a single run.

Plasma deposition is an important method for producing photovoltaic materials and has been used successfully to prepare a variety of single and multilayer materials based on silicon, germanium and related elements. In plasma deposition, a plasma containing reactive species is created from gas phase precursors and the reactive species combine to form a film on a substrate. At the current state of the art, the materials produced through plasma deposition processes have not proven to be economically competitive with fossil fuels in terms of the cost per unit of energy. The cost disadvantage is a consequence of the interplay between two primary factors in current plasma deposition processes: (1) the quality of the photovoltaic material, which can be measured in terms of photovoltaic efficiency; and (2) the rate at which the photovoltaic material can be formed. Photovoltaic efficiency is an indicator of the amount of energy produced from a unit quantity of incident light and needs to be as high as possible to reduce the unit cost of producing energy from the material. The deposition rate is an indicator of the cost of producing the photovoltaic material itself and needs to be as fast as possible to lower the unit cost of producing energy from the material. With the current paradigm for those who work in thin film photovoltaic materials, especially silicon, the efficiency of the photovoltaic material depends upon sweetspots in the deposition rate and it has been found that the very best material is formed at very slow speeds and production at these speeds cannot produce a material that is competitive with fossil fuels.

The present invention decouples the quality dependence of photovoltaic materials from the speed of production and at the same time enhances the efficiency of the materials. This invention therefore insures, for the first time, that optimum efficiency is achieved at any speed. The instant inventor has recognized that a fundamental limitation in the prior art plasma deposition processes arises from the inability to control the distribution of species created within the plasma during deposition. By its nature, a plasma is a chaotic, uncontrolled state of matter that includes a wide range of ionic, neutral and free radical species, many of which are detrimental to the quality of the deposited photovoltaic material. In the prior art deposition processes, it has not been possible to control and optimize the plasma to permit only the most desirable species to participate in the formation of the deposited film, while preventing species in the plasma that are deleterious to the quality of the film from interfering with the growth process. It has been possible to improve the quality of the photovoltaic material only by slowing the deposition rate to establish an equilibrium between the deposited film and distribution of beneficial and deleterious species in the plasma needed to achieve high quality material.

The instant inventor has recognized that only selected species within the plasma are beneficial to the quality of the film deposited in a plasma process on either a stationary or continuous web substrate. The instant inventor has accordingly devised a method and apparatus for preferentially concentrating the beneficial species of the plasma in the vicinity of the substrate surface to achieve high quality photovoltaic materials. Neutrals are the preferred deposition species within the plasma and the instant invention provides for a preferential segregation of neutrals in the vicinity of the deposition surface. Deleterious ionic species are prevented from reaching the depositing film. By rejecting the deleterious species and saturating the growth front with beneficial neutral species, the instant inventor is able to decouple the deposition rate from the quality of the photovoltaic material. As a result, high quality materials can be achieved at heretofore unprecedented deposition rates and the unit cost of obtaining energy from the materials decreases to well below that of fossil fuels.

The instant invention allows for a tremendous increase in the throughput and film formation rate in continuous web deposition processes. With the invention, the web speed can be increased without sacrificing the qualify of the thin film layers produced and without introducing defects that diminish photovoltaic efficiency. The instant invention permits an expansion of the current 30 MW manufacturing capacity to the GW regime. Photovoltaic materials can be produced on miles and miles of continuous web substrates with a machine that is the length of a football field. The technology can be applied to single layer devices as well as multilayer devices, such as the triple junction solar cell, that provide bandgap tuning that enables more efficient collection of the solar spectrum.

The impact of the invention extends well beyond solar energy and extends to the entire energy cycle. By achieving a cost-superior method of producing electrical energy, the instant inventors unlock the hydrogen economy because it now becomes possible to obtain hydrogen from water, including brackish water, at costs that obviate the need for fossil fuels. Hydrogen is the holy grail of energy supplies because it is the most ubiquitous element in the universe and leads to an inexhaustible fuel source to meet the increasing energy demands of the world. The sources of hydrogen are geographically well-distributed around the world and are accessible to most of the world's population without the need to import. Since the photovoltaic materials produced by the instant invention are thin film, flexible, light weight and can be produced by the mile, the harvesting of hydrogen from lakes, ponds, and other sources of water becomes a simple matter of spreading the photovoltaic material across the surface of water and collecting the hydrogen as it is produced from the sunlight. It is important to note that the photovoltaic material itself can be spread across land, with electrodes extending to a source of water to effect hydrogen production. Our triple junction solar cells are especially well-adapted for water splitting applications and permit the formation of hydrogen and oxygen from all sources of water, including brackish water. Because of the extremely low cost of splitting water with the instant invention, it also becomes economically viable to purify brackish or contaminated water by splitting it and recombining the hydrogen and oxygen produced to form pure water.

Displacement of fossil fuels as the primary energy source of the world has enormous consequences for the quality of life on Earth. Fossil fuels are highly polluting, contribute to global warming, and endanger the stability of the earth's ecosystem. In addition to greenhouse gases, the combustion of fossil fuels produces soot and other pollutants that are injurious to humans and animals. The use of solar energy and hydrogen as fuel sources will eliminate much of the world's pollution. Hydrogen is the ultimate clean fuel source because combustion of hydrogen produces only water as a by product and avoids the production of greenhouse gases that are so harmful to the Earth's environment. The sun fuses hydrogen for its energy and this fusion provides the photons utilized in our photovoltaic material. Up until now, a low cost method of creating electrical energy from the solar spectrum has been lacking. This invention fulfills this important need and enables a completion of an energy cycle that begins with the sun.

Other problems associated with the use of fossil fuels are also avoided with the instant invention. As worldwide use of fossil fuels has increased, the world has appreciated that fossil fuels are a truly finite resource and concern has grown that fossil fuels will become fully depleted in the foreseeable future. Scarcity raises the possibility that escalating costs could destabilize economies as well as increase the likelihood that nations will go to war over the remaining reserves.

The problems of pollution, scarcity, and conflict associated with fossil fuels are eliminated by the instant invention. The revolutionary breakthrough presented in this invention is a total energy solution that includes a machine, creative manipulation of a plasma, and high deposition rates. The machine will also include our newly developed pore cathode, discussed in pending U.S. patent application Ser. Nos. 11/447,363 and 10/043,010, the disclosures of which are incorporated by reference herein. The pore cathode assures uniformity in the thickness and activity of the deposited photovoltaic material over any width of web by utilizing pores of a size and spacing that are particularly suited to the optimal formation of a plasma. Gigawatt production rates become achievable for the first time with the instant invention in a single run. As a result, the capital costs per watt of electricity plummet and the product cost becomes low enough to effectively compete with fossil fuels.

The overall result of the instant invention will be the development of new industries that include high-valued jobs that stimulate the economy and promote the educational system. The instant inventor projects that the invention will have consequences that are as far-reaching worldwide as the advent of electricity was in prior centuries. It is the sincere hope of the instant inventors that this breakthrough will not only make energy available in a secure manner in local areas, but also free mankind from the paradigm that energy can only be found in areas of the world susceptible to wars. Advancement of human civilization to a higher level is the ultimate goal.

The present invention provides an apparatus and method to deposit high quality thin film amorphous, nanocrystalline, microcrystalline or polycrystalline materials by both generating only desired species from a gaseous precursor mixture and then depositing those desired species at a very high, and hence commercially significant rate of deposition.

There is disclosed herein a method comprising (1) generating a supply of activated species from an energy transferring gas, through the use of a plasma; (2) separating the charged species from the non charged species of the activated species, (3) transporting the non charged species from the activated species to a collision region (through the use of a substantial pressure differential between the activation region and the collision region and the transonic velocity of the energy transferring gas); (4) introducing a precursor deposition feedstock gas into said collision region and; (5) producing large quantities of desirable deposition species, without forming a plasma within the collision region via the collision of non-charged species of the energy transferring gas with molecules within the precursor deposition feedstock gas; and (6) depositing a high quality thin film material onto a substrate which is adjacent to the collision at a high deposition rate. It is further to be noted that the use of the aforementioned transonic velocity further serves to impart directional momentum to the activated species of the energy transferring gas which enables those activated species to travel the distance from the activation region to the collision region within the lifetime of the activated species of the energy transferring gas.

The most basic method comprises the steps of providing an enclosure, maintaining the interior of said enclosure at sub-atmosphere pressure, introducing an energy transferring gas into the interior to said enclosure through at least one aperture formed in a first conduit at a pressure which creates a pressure differential between the pressure of the energy transferring gas in said first conduit and the background pressure sufficient to form a plasma when exposed to a source of energizing gas of activated species of said energy transferring gas in an activation region, and operatively disposing a substrate The method further comprises the steps of providing an enclosure, maintaining the interior of said enclosure at sub-atmosphere background pressure, introducing an energy transferring gas into the interior to said enclosure through at least one aperture formed in a first conduit at a pressure which creates a pressure differential between the pressure of the energy transferring gas in said first conduit and the background pressure sufficient to form a plasma when exposed to a source of energizing gas of activated species of said energy transferring gas in an activation region, and operatively disposing a substrate interiorly of the enclosure and spacedly located remote from the activation region.

The flow rate of the energy transferring gas in the first conduit is selected so as to provide a sufficient pressure of energy transferring gas adjacent the aperture for initiating a plasma from the energy transferring gas at a power-pressure-aperture size regime which is at the substantial minimum of the Paschen curve. The size of the aperture may be reduced relative to the size of the first conduit so as to form a choke adjacent the aperture for providing the high pressure of said energy transferring gas. The time of residency of the energy transferring gas adjacent the aperture may be increased, as by a magnetic field, so that the pressure of the energy transferring gas adjacent the aperture is also increased. A cooling mechanism, such as a water jacket may be provided for the first conduit. A protective sleeve, such as a graphite sleeve, is provided by which degradation to the surface of the first conduit adjacent the aperture is reduced. The energy transferring gas is selected from the group consisting of, but not limited to hydrogen, the noble gases, CH₄, CF₄, and combinations thereof.

Further a precursor deposition gas is introduced into the interior of the enclosure through a second conduit, the point of introduction of said precursor deposition gas from said second conduit into the enclosure is spacedly disposed relative to the activation region. In this manner collisions of the high number of activated species with said precursor deposition gas define a collision region in which a high density of energized deposition species of the precursor deposition gas is generated. The precursor deposition gas is selected so that, upon collision of the activated species of said energy transferring gas therewith, one or more desired deposition species of the precursor deposition gas will be formed. The precursor deposition gas is selected from the group consisting essentially of a silicon-containing gas, a carbon-containing gas, a germanium-containing gas, a tin containing gas, and combinations thereof.

Any form of energy may be utilized to activate the energy transferring gas. When microwave energy is employed, a radiant microwave applicator is utilized to activate the energy transferring gas flowing through the aperture in the first conduit. The first conduit may be formed from a microwave transmissive material and the aperture portion thereof disposed within the radiant microwave applicator so that the activated species are primarily initiated interiorly of said first conduit. Alternatively, the first conduit may be formed from a material not transmissive to microwaves so that the activation species are primarily initiated exteriorly of the first conduit.

As mentioned hereinabove, an electromagnetic field is applied to form the plume of activated species, the volume of the plume being controllable by controlling the pressure differential which exists between the background pressure in the enclosure and the pressure of the energy transferring gas adjacent said aperture in the first conduit. The ions being separated from the neutral free radicals of the activated species via an electrically biased screen or mesh.

Preferably, the flow rate of the energy transferring gas through the first conduit relative to the background pressure which exists in the enclosure is selected to impart a velocity to the activated species of the energy transferring gas of at least about the same magnitude as the thermal velocity thereof so that the activated species are imparted with a directional velocity toward the collision region. To most effectively impart such a velocity, it is necessary that the flow be substantially transonic (near the velocity of sound so as to operate in a choke mode).

The method and apparatus of the instant invention will be capable of creating a semiconductor material having reduced density of subgap defects. The material may be silicon or a silicon alloy. The material may further optionally include one or more band gap adjusting elements. The material preferably has a non-single crystal microstructure and has fewer than 5.0×10¹⁵/cm³ subgap defects. More preferably, the semiconductor material will have fewer than 1.0×10¹⁵/cm³ subgap defects, most preferably fewer than 5.0×10¹⁴/cm³ subgap defects. The semiconductor material may further include one or more elements selected from the group consisting of germanium, carbon, oxygen, nitrogen boron, phosphorus, and tin. Preferably the semiconductor material includes germanium.

The method and apparatus of the instant invention will further create a unique form of plasma. The plasma is a filtered, neutralized plasma which is formed of a volume of gaseous species including energized and non-energized neutral gaseous species and the volume is substantially devoid of ionized gaseous species.

The above-described and other objects, advantages and features of the instant invention will become more apparent upon reference to the Drawings, the Detailed Description Of The Drawings, the Claims which follow hereinafter.

### BRIEF DESCRIPTION OF THE DRAWINGS

FIG. 1 is a schematic depiction of a PECVD silane plasma and some of the activated species that form within the plasma “zoo” (not shown are the are the products resulting from gas phase nucleation);

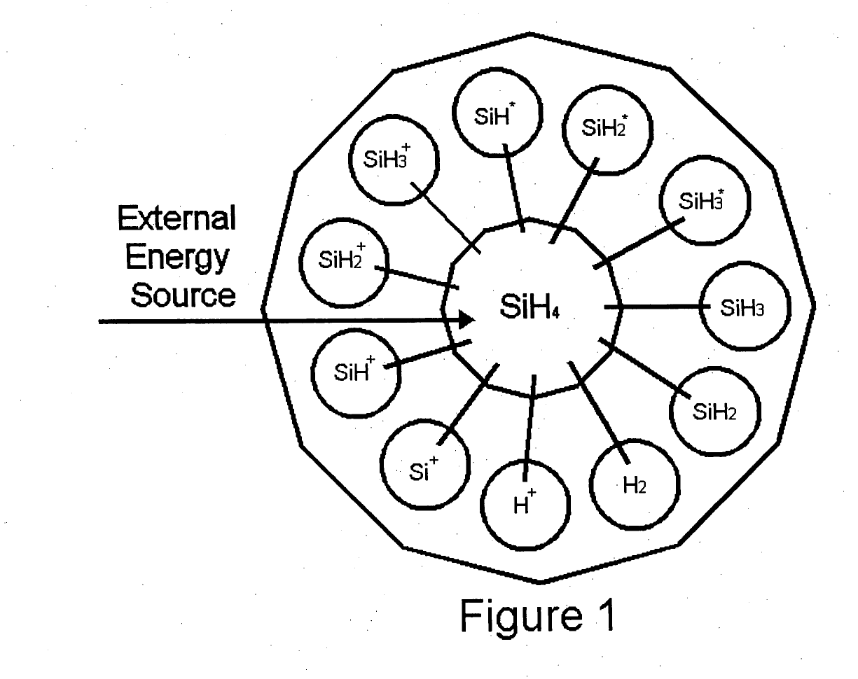

FIG. 2 is a perspective view, partially cut-away, illustrating the interior of a evacuated deposition enclosure of the instant invention, in which enclosure a plume of activated species of an energy transferring gas is directed pass through an electrically biased screen or mesh which allows only the free radicals of the activated species to collide with a precursor deposition gas for the generation of energized deposition species and the deposition of those deposition species onto the surface of a remotely positioned substrate; and

FIG. 3 is a schematic view of a deposition apparatus according to FIG. 2 and further including means for roll to roll deposition onto a continuous web of substrate material.

### DETAILED DESCRIPTION OF THE INVENTION

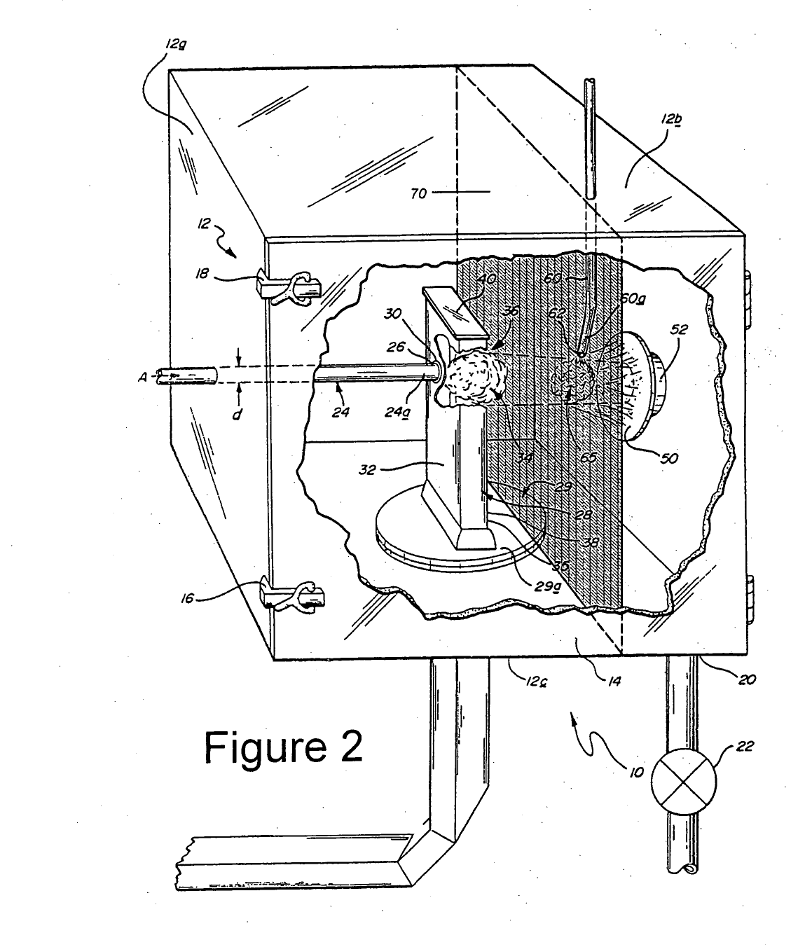

Referring now to the drawings and particularly to FIG. 2, there is illustrated therein a perspective view, partially cut-away, of a reaction apparatus, generally referenced by the numeral 10. Functionally, the apparatus 10 is adapted to generate a plume of activated species from an energy transferring gas introduced into the interior thereof. The activated species of the energy transferring gas may then be directed towards a region populated by a high density of a precursor deposition gas, whereby neutral free radicals of the activated species after being separated from the ions of the activated species collide with the precursor deposition gas so as to form desired energized deposition species. These energized deposition species will subsequently deposit relatively high quality, thin film layers of silicon, germanium, carbon and combinations thereof, upon a substrate operatively disposed in proximate relationship to the collision region.

The apparatus 10 as depicted in FIG. 2, includes an evacuable enclosure 12. The enclosure 12 may include a pivotally mounted front face 14 which functions as a door for loading and removing substrates (when such single batch substrates are used) from the interior of the enclosure. The inner periphery of the door 14 is equipped with one or more vacuum seal rings (not shown) and one or more latches, such as 16 and 18, which latches are adapted to compress the seal rings for assuring an airtight closure between ambient conditions externally of the enclosure and vacuum conditions interiorly of said enclosure. The evacuated enclosure 12 further includes a pump-out port 20 in the bottom wall 12c thereof adapted for connection to a powerful vacuum pump 22 which is employed to: (1) exhaust depleted reaction products from the hollow interior thereof; and (2) to maintain the interior of said enclosure 12 at an appropriate sub-atmospheric pressure. As will be explained in greater detail hereinafter, the background pressure will be carefully selected to initiate and sustain the high rate deposition process carried out interiorly of the enclosure. Deposition rates of greater than 20 to 50 Angstroms per second may be achieved within the parameters of the present invention. More preferably, deposition dates of greater than 100 Angstroms per second and most preferably greater than 300 Angstroms per second may be achieved using the principles of the present invention. This is because the rate of deposition has been decoupled from the quality of the deposited material using the principles of the present invention. This in turn reduces the cost of production of products such as photovoltaic panels, and increases the throughput of existing machines making what was a 30 MW/year production machine into a 300 MW/year machine.

The apparatus 10 further includes at least a first elongated conduit 24 of diameter d, wherein d is preferably between about 0.5 to 3.0 cm, extending through a side wall 12a into the interior of said evacuated enclosure 12. The first, hollow conduit 24 includes at least one portion, the distal end portion 24a thereof, having an aperture 26 formed therein. The first conduit means 24 and the aperture portion 24a thereof are adapted to, respectively, transmit and introduce an energy transferring gas from a source (not shown) into the interior of said evacuated enclosure 12, preferably to a point immediately adjacent apparatus adapted to provide activated species from said energy transferring gas. In the preferred embodiment depicted in FIG. 2, the activation apparatus will take the form of a radiant microwave applicator 28, discussed in greater detail hereinbelow. In one preferred embodiment, the first conduit 24 is adapted to introduce an energy transferring gas selected from the group consisting essentially of hydrogen (H₂), methane (CH₄), the noble gases and combinations thereof. Alternatively, and in another preferred embodiment, the above mentioned energy transferring gases may also include one or more diluent or dopant gases, including, but not limited to, O₂, NH₃, N₂, NH₄, CH₄, PH₃, PH₅, BF₃, BF₅, B₂H₆, BH₄, and combinations thereof.

Regardless of the composition of the energy transferring gas employed, the aperture 26 formed at the distal end of the first conduit 24 must be capable of delivering a selected flow rate (as measured in terms of SCCM, i.e., standard cubic centimeters per minute) of said energy transferring gas. The flow rate is selected to provide a sufficient pressure of the energy transferring gas adjacent said aperture 26 for initiating the activation of said energy transferring gas at a power-pressure aperture size regime which is at the substantial minimum of the modified Paschen curve.

The first conduit 24 may further include means reducing the flow path for the energy transferring gas to create a “choke-condition” in the first conduit 24 adjacent the aperture 26 so as to provide a localized high pressure of the energy transferring gas. As used herein, the term “choke condition” refers to the condition which occurs when the speed of the energy transferring gas passing through the aperture 26 in the first conduit 24 reaches transonic speed. The choke condition generally is that condition which occurs in compressible gas or fluid flow when, for a conduit of a uniform size, the speed of the gas passing through said conduit reaches transonic velocity. It is at this condition that any rise in the flow rate of the energy transferring gas results in an increase in pressure rather than velocity. It is also this condition which defines the choke mode and it is precisely this effect which allows the pressure to be increased for operation at the substantial minimum of the Paschen curve. This localized high pressure creates a sufficient pressure zone for the energy transferring gas flowing through the first conduit adjacent the aperture portion 24a so that a plasma may be initiated and maintained at a power level which can be independently controlled. In an alternative embodiment, the pressure within the aperture portion 24a of the first conduit 24 may be easily controlled by employing a solenoid therewithin, which solenoid may be selectively constricted or relaxed so as to regulate the flow rate of energy transferring gas passing therethrough and hence the pressure which exists adjacent said aperture portion 24a.

Note that, and as will be specified in detail hereinafter, the activated species of the energy transferring gas forms a plume of pressure isobars adjacent the aperture portion of the first conduit 24, which plume defines an activation region of activated species. As will also be detailed hereinafter, the boundaries of the plume of activated species are specified by the pressure differential which exists between the gas flowing through the interior of the first conduit and the background pressure existing in the interior of the enclosure. As should be apparent, material which is sputtered from the surface of the first conduit 24 would degrade the quality of the activated species in the plume 34; and more importantly, the quality of the subsequently deposited thin film material would correspondingly deteriorate. Thus, a protective overcoat is preferably fabricated from a material which is resistant to a high temperature sputtering environment; or alternatively, a material which is relatively benign when incorporated into the ultimately deposited film. In a preferred embodiment, graphite is employed as the material from which the protective overcoat is fabricated. Graphite is not only highly resistant to high temperature and high temperature sputtering processes, but when the apparatus 10 is employed for the deposition of semiconductor alloy materials, graphite is substantially electrically benign to the desired characteristics of that deposited semiconductor film.

Returning now to FIG. 2, the deposition apparatus 10 further includes the aforementioned microwave applicator 28 which applicator is adapted to deliver electromagnetic energy at 2.45 GHz to the energy transferring gas flowing through the first conduit 24. While the applicator 28 is depicted as a radiant microwave applicator, said applicator may be selected to deliver any type of energy selected from the group consisting essentially of microwave energy, r.f. energy, low frequency a.c. energy, or photo-energy in the form of a high intensity pulsed laser. However, and as previously mentioned, since microwave energy can most effectively provide a high density, large volume plasma of activated species, the applicator 28 is preferably formed as a microwave applicator, preferably a radiant microwave applicator (as opposed to slow-wave applicator) adapted to transmit at least 1.0 kilowatt of microwave power and preferably 5 kilowatts or more of microwave power at a frequency of 2.45 GHz.

As clearly depicted in FIG. 2, the applicator 28 is an elongated, hollow, generally rectangularly shaped, nickel or nickel-plated copper waveguide structure adapted to transmit microwave energy from a magnetron (not shown) to the energy transferring gas introduced into the enclosure from the first conduit 24. The waveguide applicator 28 enters the enclosure 12 through a microwave transmissive window 29, which window is vacuum sealed to a bottom face 12c of the enclosure. This type of vacuum sealed window 29 is fully disclosed and well known in the art. The microwave applicator 28 is seated upon the upper, interior plate 29a of that window 29.

In order to achieve the function of coupling the introduced microwave energy to the introduced energy transferring gas, the first conduit 24 extends through an aperture 30 formed in the side face 32 of the waveguide 28 for receiving the energy transferring gas. Accordingly, aperture 30 is adapted to facilitate the passage of the first conduit 24 and the energy transferring gas carried therewithin into an activation region 34 formed adjacent the aperture portion 24a of the first conduit 24 so that the plume of activated species extends from the interior of said applicator 28.

The radiant microwave applicator 28 further includes cut-away section 36 formed in the face 35 thereof opposite the face 32 in which the aperture 30 is formed. The cut-away section 36 has a diameter larger than the diameter of the aperture 30 and preferably at least about 2 inches so as to provide for the movement of expanding pressure isobars of the plume of activated species without having those activated species degrade too much of the microwave applicator material. It should therefore be understood that the applicator cut-away section 36 is adapted to provide a means of directed escape for the activated species of the energy transferring gas from within said applicator 28. The microwave applicator 28 further includes a closed end plate 40 to prevent the escape of unused microwave energy into the interior of the evacuated enclosure 12. It is to be noted that the maximum size of the cut-away section 36 of face 35 of the applicator 28 will be determined by balancing the facts that (1) the smaller the opening is made, the more material therefrom will be etched away, but the more the microwave energy is confined; while (2) the larger the opening is made, the less material is etched therefrom, but the more the microwave energy leaks into the enclosure. The cutaway section 36 may further include a microwave absorptive or reflective screen or other means adapted to prevent the microwave energy from entering the enclosure. This becomes particularly significant as the pressure differential between the background pressure and the pressure of the energy transferring gas in the first conduit is reduced to approach the aforementioned factor of at least 5.

The deposition apparatus 10 further includes at least one remotely located, generally planar substrate 50 operatively disposed within the enclosure 12 and at least spaced a distance from the activation region 34 sufficient to prevent said thin film material depositing thereupon from direct exposure to the electrons present in that region. The apparatus further includes at least one electrically biased screen or mesh 70. The screen(s) or mesh(s) are disposed between the energy transferring gas activation region 34 and the collision region 65. The screen 70 is electrically biased. The bias may be any of 1) a positive bias to repel the ionic species with the plume of activated species as it passes therethrough, 2) a negative bias to attract and neutralize the charged ionic species, or 3) a plurality of screens with opposite biases. The electrically biased screen 70 also acts (along with the positive ions) to attract the electrons within the plume and insure that they do not reach collision region 65. The screen 70 is spaced far enough from the plasma activation region 34 so as to insure that the screen is not destroyed by the plasma. The screen is also made of a material that is resistant to the effects of the plasma. Preferred materials include graphite, tungsten, nickel and nickel plated materials. The screen 70 is also spacedly disposed from the collision region 65 such that any electrons which pass through the screen before they are captured thereby do not impinge upon the collision region, as such could create undesirable species in the depositing materials. The Apparatus may further include a plurality of meshes or screens, each one providing an additional degree of separation (fractionation) of the charged species from the neutral species within the plume of activated species.

The apparatus 10 may further preferably include means 52 adapted to heat and or apply an electrical or magnetic bias to the substrate 50. It is to be understood, however, that the use of heat or a bias is not required to practice the invention disclosed herein. In a preferred embodiment, the substrate 50 is operatively disposed so as to be substantially aligned with the first conduit 24 so that a flux of the activated species generated in the activation region 34 can be directed thereat for deposition thereupon.

In a preferred embodiment, the deposition apparatus 10 may also be equipped with a second elongated, hollow conduit 60 having at least one aperture 62 formed at the distal end 60a thereof. The apertured end 60a of the second conduit 60 extends through the top wall 12b of the enclosure 12 and into the interior thereof so that the aperture 62 terminates in close proximity to said substrate 50. The second conduit 60 is adapted to deliver a flow of a precursor deposition gas from a source (not shown) into a collision region 65 which is created adjacent said substrate 50. The precursor deposition gas is typically selected from the group consisting essentially of a silicon-containing gas, a germanium-containing gas, a carbon-containing gas, and combinations thereof. Specific examples of preferred precursor deposition gases include, but are not limited to, SiH₄, SiF₄, Si₂H₆, GeH₄, Ge₂H₆, GeF₄, CH₄, C₂H₆, and combinations thereof.

As previously mentioned, the precursor deposition gas is introduced by the second conduit 60 into the collision region 65. The collision region 65 is disposed in the path of travel of the neutral free radicals of the activated species of the energy transferring gas as those activated species are directed from said activation region 34 toward the substrate 50. In this manner neutral free radical activated species from the activation region 34 are directed towards the collision region 64 where said species collide and interact with said precursor deposition gas so as to create a desired energized deposition species. It is to be noted that the collision region 64 should be disposed a distance from said substrate 50 selected so that the desired deposition species created in the collision region 64 will uniformly deposit over the entire surface of the substrate 50 without encountering multiple collisions with either other activated species or other deposition species formed in the collision region. It should also be noted that as the pressure changes from the activation region to the collision region, so does the mean-free-path length of the activated species. The path length increases as the pressure decreases such that a plasma can be formed in the activation region and cannot be formed in the collision region. In a preferred embodiment, the background pressure to which the enclosure 12 is evacuated provides for a mean free path for the free radical deposition species of approximately 1-15 cm. Therefore, by spacing the substrate a distance of 1-15 cm from the collision region, the entire surface thereof will be covered with a uniform thin film of material.

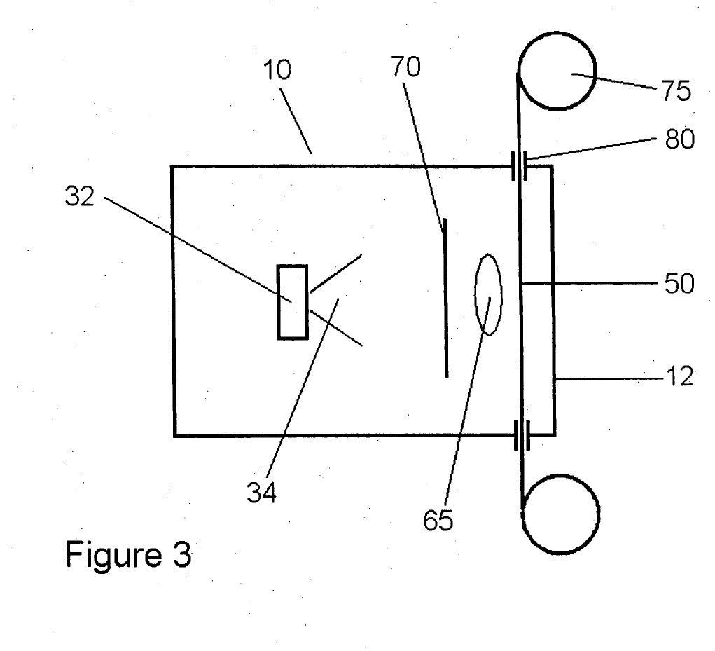

Finally, with reference to FIG. 3, there is shown a schematic depiction of an embodiment of an apparatus of the present invention which is adapted to deposit semiconductor material on an elongated sheet of substrate 50, such as a thin elongated sheet of a metal, such as stainless steel, or a plastic such as Kapton. The substrate is payed off from and taken up by rollers 75, which may be external to the deposition apparatus 10. The substrate may be passed into and out of the deposition apparatus 10 using gas gates 80. As the substrate 50 passes into and out of deposition apparatus 10, semiconductor material may be deposited thereon by the activated species in the collision region 65, as is described with respect to FIG. 2 above. It should be noted that multiple chambers such as that shown in FIG. 3 may be connected together in series to make multi-layered devices, (e.g. triple junction, thin film, photovoltaic devices). It should also be noted that for large area deposition, the gas supply means may include a pore electrode as described in U.S. Patent Application Publication No. 20040250763, invented by S. R. Ovshinsky.

While the apparatus described hereinabove has been designed so as to be particularly adapted to carry out the principles of the instant invention, it is to be understood that other modified embodiments of this apparatus may be used with equal advantage and it is the practice of the method rather than the specific apparatus which defines the true scope of the instant invention. It will, however, be necessary to make periodic references to the aforedescribed apparatus in order to more clearly explain the practice of the operative concepts of the method disclosed herein.

In the most general terms of one embodiment of the instant invention, there is disclosed a novel method of generating activated species from an energy transferring gas in an activation region 34 which is located interiorly of the evacuated enclosure. The ions of the activated species of the energy transferring gas may then be separated from the neutral free radicals thereof. The neutral free radicals are then directed to collide with a precursor deposition gas in a collision region 65 so as to yield a high density of only desired energized deposition species, which energized species react with the exposed surface of a substrate spacedly located relative to the activation region.

In operation, the method of the subject invention is carried out in a evacuated enclosure or chamber of the type generally described with reference to FIG. 2. The evacuated enclosure is first evacuated to a background pressure which, in conjunction with the substantially transonic flow rate of the energy transferring gas interiorly of the first conduit, will allow for the subsequent initiation and maintenance of a plasma of activated species of the energy transferring gas, which plasma has been carefully controlled to occur at the substantial minimum of the Paschen curve. It therefore becomes critical to select a pump which is sufficiently powerful to evacuate the enclosure to the low background pressure, despite the high flow rate of energy transferring gas constantly introduced thereinto. In one preferred embodiment, the pump is capable of evacuating and maintaining the enclosure to a background pressure of less than about 50 torr, and preferably in the range of approximately 0.01 mtorr to 10 mtorr, although the background pressure need not be limited to any given value.

As specifically described, there is introduced into the interior of the evacuated enclosure, inter alia, the energy transferring gas, which introduction is accomplished by a first conduit preferably having at least one aperture formed at the distal end thereof. The aperture is typically dimensioned to have a diameter of between about 0.25 to 3.0 cm and may be equipped with a solenoid operated aperture reduction structure and/or a protective overcoat, both of which elements have been fully described hereinabove.

The energy transferring gas is typically selected from the group consisting of the noble gases, hydrogen, methane, etchant gases, and combinations thereof. In a preferred embodiment, the energy transferring gas is helium, which when appropriately excited, yields long-lived neutral activated species. Additionally, the energy transferring gas (or alternatively the precursor deposition gas) may include a number of diluent or dopant gases including, but not limited to, O₂, NH₃, N₂, NH₄, H₂, CH₄, PH₃, PH₅, BF₃, BF₅, B₂H₆, BH₄, and combinations thereof. The function of the diluent or dopant gas is to provide a source of an element to be incorporated into the deposited film. For example, if a thin film of silicon/germanium alloy material is being deposited upon the spacedly disposed substrate, the film may be rendered slightly p-type by the addition of small amounts of a p-type dopant, such as BF₃, into the flow of the energy transferring gas (or deposition precursor gas). Alternatively, in the deposition of a layer of insulating SiOx material, it will be necessary to include small amounts oxygen in the stream of the energy transferring gas. Regardless of composition, it is important that the energy transferring gas be delivered through said first conduit to a point immediately adjacent the activation means, such as directly into the interior of the radiant microwave applicator discussed hereinabove.

It should be noted that the energized species formed from the activation gas and/or the deposition precursor gas may be all of or some portion of the total gas molecule used. For example if SiH₄ is used as one of the deposition precursor gases, then the activated species thereof may include activated forms of SiH₄, SiH₃, SiH₂, Si_{H}, Si, and H, not all of which will form or be desirable depositing species.

While the activation energy may be selected from the group consisting of a.c. energy, d.c. energy, r.f. energy, microwave energy, photoactivation energy, and combinations thereof. In fact, any electromagnetic energy from 0 Hz to 5 Ghz could be used to activate the energy transferring gas. In a preferred embodiment, the activation energy is microwave energy and the activation means is a radiant microwave applicator, such as the aforementioned radiant microwave waveguide which extends into the interior of the evacuated enclosure. The radiant microwave applicator is adapted to provide about 1-10 kilowatts of microwave power at a frequency of 2.45 GHz. The energy transferring gas is delivered from the aperture in the first conduit through an opening hole formed in the side wall of the microwave applicator into an activation region located at least partially within the hollow interior of said applicator. The activation region is clearly defined as that region in which an ionized plasma of activated species of the energy transferring gas is formed. The high flow rate of the energy transferring gas exiting the first conduit relative to the background pressure within the enclosure also defines a series of pressure isobars which serve to limit the volume occupied by the ionized plasma of the activated species of that energy transferring gas.

The energy transferring gas is preferably delivered by the first conduit at a flow rate of at least about 100 SCCM, and more preferably approximately between 100-2000 SCCM. In this way, it is possible to maintain a preferred pressure differential of at least about a factor of five times difference between the background pressure that exists within the interior of the enclosure (less than about 50 torr, and preferably 0.1-10 mtorr) and the pressure of the energy proximate the aperture of the first conduit (which pressure may be as high as about 10-30 torr). It should be apparent that the pressure within any given isobar decreases with distance away from the aperture in the firs conduit. Therefore, at any given power, the slope of the Paschen curve will provide a pressure-determined boundary of the activation region.

After evacuating the enclosure, applying the electromagnetic field of microwave energy by means of the radiant microwave applicator and introducing a sufficient flow of the energy transferring gas (which, in conjunction with the background pressure in the enclosure and the power of the electromagnetic field), ignite a plasma of activated species from the high density of the energy transferring gas residing within the activation region; activated species of the energy transferring gas travel towards the collision region 65 illustrated in FIG. 2. The activated species of the energy transferring gas are in fact driven towards the collision region due to the high flow rate of the energy transferring gas exiting from the first conduit. The velocity which the flow rate imparts to the energy transferring gas is, at least initially, transonic, and in any case, must be of at least the same magnitude as the thermal velocity of said activated species. In other words, if the directional momentum imparted to the energy transferring gas is not substantially the same as or greater than the thermal velocity, the directional momentum will be lost in the low background pressure which exists in the enclosure. Along the path from the activation region 34 to the collision region 65, the activated species encounter the electrically biased screen(s) 70, which as discussed above effects the separation of the ions and neutral free radicals of the activated species. The neutral free radicals pass through the screen while the ions are repelled by the screen and do not pass therethrough. The neutral free radicals continue on to the collision area 65 where they interact with the precursor deposition gas.

It is to be recalled that the location of the collision region is defined by a second conduit having at least one aperture disposed at the distal end thereof, which distal end of the conduit extends into the interior of the evacuated enclosure and terminates in close proximity to the substrate. The function of the second conduit is to deliver the precursor deposition gas into the collision region 65 so that the neutral activated species of the energy transferring gas may interact with the precursor gas to yield an energized deposition species. Preferred precursor deposition gases delivered to the collision region include, but are not limited to, silicon containing gases, germanium containing gases, carbon containing gases, tin containing gases and combinations thereof. The precursor deposition gas is typically delivered into the collision region at a flow rate of at least about 10 SCCM and preferably between about 10 and 200 SCCM, with a preferred flow rate of between about 25 and 100 SCCM, and a most preferred flow rate of approximately 40 SCCM.

In the collision region, activated species of the energy transferring gas (i.e., helium) interact with the precursor deposition species (e.g., silane) in the following manner:

He*+SiH₄->SiH₃*+H+He

The resulting SiH₃*, H and He then migrate from the collision region and the neutral free radicals are deposited upon the exposed surface of the substrate, which substrate is located a distance from the collision region that is within the length of the mean free path of the energized deposition species. The He, because it is a non-excited neutral species, is now a harmless by product, does not cause ionic bombardment of the depositing material or in any other way deleteriously effect the growing film. The mean free path of the energized deposition species is the distance that the energized deposition species may travel without colliding with either other deposition species (such as free radicals) or encountering a second collision with activated species of the energy transferring gas. The mean free path of the energized deposition species should be approximately the length of the longest dimension of the substrate so that the uniform deposition of the energized deposition species over the entire exposed surface of the substrate is assured.

As is well known to those skilled in the art, the length of the mean free path of the energized deposition species is directly dependent upon the background pressure existing within the evacuated enclosure through which those species will diffuse. For example, if the background pressure within the enclosure were relatively high, i.e., approximately one torr, the mean free path of the energized deposition species would be quite short (on the order of 1 mm or less). If on the other hand, the background pressure of the evacuated enclosure is maintained at substantially sub-atmospheric levels, as approximately 1 millitorr, the mean free path of the energized deposition species will be considerably longer, on the order of 5-10 cm. It can thus be appreciated that the size of the substrate upon which the energized deposition species is to be deposited, will be one of the critical factors used in determining the length of the mean free path, and correspondingly, the background pressure at which the evacuated enclosure must be maintained.

It should be equally apparent that once the background pressure of the evacuated enclosure is determined, and the deposition rate is selected, each of the other parameters critical in initiating a plume of a given volume of activated species of the energy transferring gas are likewise determined. As was discussed hereinabove, as a rule of thumb, the flow rate of the energy transferring gas through the first conduit must be sufficient to create a pressure differential of at least about a factor of five between the energy transferring gas and the background pressure of the evacuated enclosure for the uniform deposition of energized deposition species onto a substrate having a surface area of about 100 square cm. Thus, knowing the required length of the mean free path, the background pressure may be selected, and this background pressure dictates the possible range of flow rates at which the energy transferring gas must be introduced into the enclosure in order to maintain a significant pressure differential between the background pressure and the flow within the first conduit. This also determines the size aperture which will provide transonic flow at that flow rate of energy transferring gas.

Taking the usable range of flow rates of the energy transferring gas for a given background pressure, it then becomes possible to use the Paschen curve to determine an optimized power/pressure regime in which to operate for a given volume of activated species. At a given power/pressure/aperture size regime, it is possible to determine the approximate percentage of the energy transferring gas which has been excited to form the activated species, (the typical range is 1-5% of, for example, He being promoted to the He* activated species). Knowing this percentage allows the operator to regulate the flow rate of the precursor deposition gas into the collision region, thereby maximizing the ratio of He* to precursor gas molecules to avoid the possibility of multiple collisions between the energized deposition species and the precursor deposition gas.

It should noted that the collision region may consist of a unique form of plasma. The unique plasma is a filtered, neutralized plasma which is formed of a volume of gaseous species including energized and non-energized neutral gaseous species but has a substantially reduced fraction of ionized gaseous species. Preferably the fraction of ionized gaseous species may be reduced by at least 50%, more preferably by at least 75% and most preferably by at least 90%.

The method and apparatus of the instant invention will be capable of creating a semiconductor material having reduced density of subgap defects. The material may be silicon or a silicon alloy. The material may further optionally include one or more band gap adjusting elements. The material preferably has a non-single crystal microstructure and has fewer than 5.0×10¹⁵/cm³ subgap defects. More preferably, the semiconductor material will have fewer than 1.0×10¹⁵/cm³ subgap defects, most preferably fewer than 5.0×10¹⁴/cm³ subgap defects.

It should be recognized that the foregoing description and discussion are merely meant to illustrate the principles of the instant invention and not meant to be a limitation upon the practice thereof. It is the following claims, including all equivalents, which are meant to define the true scope of the instant invention.

What is claimed is:

1. A method of depositing a material onto a substrate, said method comprising the steps of:
providing an evacuated deposition chamber;
maintaining the interior of said evacuated deposition chamber at a sub-atmospheric background pressure;
introducing an energy transferring gas into the interior of said evacuated deposition chamber;
activating said energy transferring gas in an activation region so as to form an ionized plasma of activated species which includes charged and non-charged species;
separating said charged species from said non-charged species of said activated species;
introducing a precursor deposition gas into a collision region within the interior of said evacuated deposition chamber, said collision region being remote from said activation region;
directing said non-charged species to said collision region, said non-charged species interacting with said precursor deposition gas to form one or more desired depositing species without forming an ionized plasma in said collision region;
providing a substrate adjacent said collision region; and
depositing said desired depositing species onto said substrate.

2. The method of claim 1, wherein said step of separating said charged species from said non-charged species of said activated species includes passing said activated species through at least one electrically biased mesh or screen.

3. The method of claim 2, wherein said at least one electrically biased mesh or screen includes at least one positively biased mesh or screen.

4. The method of claim 1, wherein said energy transferring gas is selected from the group consisting of hydrogen, the noble gases, CH₄, CF₄, and combinations thereof.

5. The method of claim 1, wherein said precursor deposition gas is one or more gases selected from the group consisting of a silicon-containing gas, a carbon-containing gas, a germanium-containing gas, a tin containing gas, and combinations thereof.

6. The method of claim 5, wherein said precursor deposition gas is one or more gases selected from the group consisting of SiH₄, SiF₄, Si₂H₆, GeH₄, GE₂H₆, GeF₄, CH₄, and combinations thereof.

7. The method of claim 6, wherein said energy transferring gas is helium, said activated species of said energy transferring gas include helium ions and free radicals and said precursor deposition gas is SiH₄.

8. The method of claim 4, wherein either said precursor deposition gas or said energy transferring gas further includes one or more gases selected from the group consisting of O₂, NH₃, N₂, NH₄,CH₄, PH₃, PH₅, BF₃, BF₅, B₂H₆, BH₄, and combinations thereof.

9. The method of claim 1, where said step of activating said energy transferring gas includes utilizing r.f. energy to activate said energy transferring gas.

10. The method of claim 1, where said step of activating said energy transferring gas includes utilizing microwave energy to activate said energy transferring gas.

11. An apparatus for depositing a material onto a substrate, said apparatus comprising:
an evacuated deposition chamber;
means for introducing an energy transferring gas into an activation region in said evacuated deposition chamber;
means for introducing activation energy to into said activation region, whereby said activation energy activates said energy transferring gas and forms an ionized plasma of activated species which includes charged and non-charged species;
means for introducing a precursor deposition gas into a collision region remote from said activation region in said evacuated deposition chamber;
means for disposing a substrate within said evacuated deposition chamber, said substrate disposed remote from said activation region and adjacent said collision region;
means for separating said charged species from said non-charged species of said activated species, said means for separating disposed between said activation region and said collision region; and
means for directing said non-charged species from said activation region to said collision region whereby said non-charged species collide with said precursor deposition gas to form one or more desired depositing species without forming an ionized plasma in said collision region and said one or more desired depositing species then deposit onto said substrate.

12. The apparatus of claim 11, wherein said means for introducing activation energy to into said activation region comprises a means for transferring microwave energy into said activation region.

13. The apparatus of claim 11, wherein said means for introducing activation energy to into said activation region comprises a means for transferring r.f. energy into said activation region.

14. The apparatus of claim 11, wherein said means for disposing a substrate within said evacuated deposition chamber includes means to pass an elongated sheet of substrate into said evacuated deposition chamber, past said collision region and back out of said evacuated deposition chamber.

15. The apparatus of claim 14, wherein said means to pass an elongated sheet of substrate into said evacuated deposition chamber, past said collision region and back out of said evacuated deposition chamber includes gas gate isolation devices.

16. The apparatus of claim 14, wherein said means to pass an elongated sheet of substrate into said evacuated deposition chamber, past said collision region and back out of said evacuated deposition chamber includes payoff and take-up rollers for said elongated sheet of substrate material.

17. The apparatus of claim 11, wherein said means separating for said ions from said free radicals includes at least one electrically biased screen or mesh.

18. The apparatus of claim 17, wherein said at least one electrically biased mesh or screen includes at least one positively biased mesh or screen.

19. The apparatus of claim 11, wherein either said means for introducing a precursor deposition gas or said means for introducing an energy transferring gas comprises a means to introduce one or more gases selected from the group consisting of O₂, NH₃, N₂, NH₄, CH₄, PH₃, PH₅, BF₃, BF₅, B₂H₆, BH₄, and combinations thereof.

20. The apparatus of claim 11, wherein said means for introducing a precursor deposition gas comprises a means to introduce one or more gases selected from the group consisting of a silicon-containing gas, a carbon-containing gas, a germanium-containing gas, a tin containing gas, and combinations thereof.

21. The apparatus of claim 20, wherein said means for introducing a precursor deposition gas comprises a means to introduce one or more gases selected from the group consisting of SiH₄, SiF₄, Si₂H₆, GeH₄, GE₂H₆, GeF₄, CH₄, and combinations thereof.

22. In a deposition apparatus, including
an evacuated deposition chamber;
an energy transferring gas inlet directing energy transferring gas to an activation region within said evacuated deposition chamber;
activation energy directed to said activation region; whereby the pressure of the energy transferring gas and the intensity of the activation energy forms an ionized plasma of activated species in said activation region; said activated species including charged and non-charged species;
a deposition precursor gas inlet directing a deposition precursor gas to a collision region within said evacuated deposition chamber; said collision region remote from said activation region;
means for directing said activated species from said activation region to said collision region, said activated species colliding with said deposition precursor gas in said collision region, thereby forming depositing species; the pressure within said collision region insufficient to form an ionized plasma when exposed to said activated species;
a substrate disposed adjacent said collision region onto which said depositing species are deposited;
the improvement comprising:
means for separating the charged species from the non-charged species of said activated species disposed between said activation region and said collision region, said means for separating providing for an increased concentration of non-charged species between said means for separating and said collision region than between said activation region and said means for separating.

23. An apparatus comprising:
an evacuated deposition chamber;
an activation region which forms an ionized plasma within said evacuated deposition chamber;
a collision region which is incapable of forming an ionized plasma within said evacuated deposition chamber, remote from said activation region; and
a means for separating charged species from non-charged species disposed between said activation region and said collision region.

24. The apparatus of claim 20, wherein said means separating charged species from non-charged species comprises an electrically biased screen or mesh.

25. A semiconductor material comprising:
silicon or a silicon alloy and optionally one or more band gap adjusting elements;
said silicon or a silicon alloy has a non-single crystal microstructure and has fewer than 5.0×10¹⁵/cm³ subgap defects.

26. The semiconductor material of claim 25, wherein said silicon or a silicon alloy has fewer than 1.0×10⁵/cm³ subgap defects.

27. The semiconductor material of claim 25, wherein said silicon or a silicon alloy has fewer than 5.0×10¹⁴/cm³ subgap defects.

28. The semiconductor material of claim 25, wherein said silicon or a silicon alloy further includes one or more elements selected from the group consisting of germanium, carbon, oxygen, nitrogen boron, phosphorus, fluorine and tin.

29. The semiconductor material of claim 28, wherein said silicon or a silicon alloy includes germanium.

30. A filtered, neutralized, plasma, said plasma comprising:
a volume of gaseous species including energized and non-energized neutral gaseous species; said volume having a substantially reduced fraction of ionized gaseous species.

31. The filtered, neutralized, plasma, of claim 30, wherein said energized and non-energized neutral gaseous species include energized and non-energized neutral gaseous species of one or more gases selected from the group consisting of a silicon-containing gas, a carbon-containing gas, a germanium-containing gas, a tin containing gas, and combinations thereof.

32. The filtered, neutralized, plasma, of claim 31, wherein said energized and non-energized neutral gaseous species include energized and non-energized neutral gaseous species of one or more gases selected from the group consisting of SiH₄, SiF₄, Si₂H₆, GeH₄, GE₂H₆, GeF₄, CH₄, and combinations thereof.

33. The filtered, neutralized, plasma, of claim 31, wherein said energized and non-energized neutral gaseous species further includes energized and non-energized neutral gaseous species of one or more gases selected from the group consisting of hydrogen, the noble gases, CH₄, CF₄, and combinations thereof.

34. The filtered, neutralized, plasma, of claim 31, wherein said energized and non-energized neutral gaseous species further includes energized and non-energized neutral gaseous species of one or more gases selected from the group consisting of O₂, NH₃, N₂, NH₄, CH₄, PH₃, PH₅, BF₃, BF₅, B₂H₆, BH₄, and combinations thereof.

35. The filtered, neutralized, plasma, of claim 30, wherein said substantially reduced fraction of ionized gaseous species is at least a 50% reduction of ionized species.

36. The filtered, neutralized, plasma, of claim 35, wherein said substantially reduced fraction of ionized gaseous species is at least a 75% reduction of ionized species.

37. The filtered, neutralized, plasma, of claim 36, wherein said substantially reduced fraction of ionized gaseous species is at least a 90% reduction of ionized species.
